(19) United States
(12) Patent Application Publication
(10) Pub. No.: US 2024/0055345 A1
(43) Pub. Date: Feb. 15, 2024

(54) ALTERNATING HIGH K LAYERS ON GLASS PILLARS FOR SUPER CAPACITORS ON GLASS SUBSTRATES

(71) Applicant: Intel Corporation, Santa Clara, CA (US)

(72) Inventors: Brandon C. MARIN, Gilbert, AZ (US); Srinivas V. PIETAMBARAM, Chandler, AZ (US); Gang DUAN, Chandler, AZ (US); Suddhasattwa NAD, Chandler, AZ (US); Jeremy D. ECTON, Gilbert, AZ (US); Rahul N. MANEPALLI, Chandler, AZ (US)

(21) Appl. No.: 17/886,278

(22) Filed: Aug. 11, 2022

(51) Int. Cl. H01L 23/522; H01L 49/02; H01G 11/70; H01L 23/15

(52) U.S. Cl. CPC H01L 23/5223; H01L 28/40; H01G 11/70; H01L 23/15

(57) ABSTRACT

Embodiments disclosed herein include electronic packages. In an embodiment, the electronic package comprises a substrate, where the substrate comprises glass. In an embodiment, a pillar is over the substrate, and a capacitor is over the pillar. In an embodiment, the capacitor comprises a first conductive layer on the pillar, a dielectric layer over the first conductive layer, and a second conductive layer over the dielectric layer.

### TECHNICAL FIELD

Embodiments of the present disclosure relate to electronic packages, and more particularly to a glass substrate with super capacitors provided over the glass substrate.

### BACKGROUND

In order to provide power regulation to one or more dies in an electronic package, voltage regulator (VR) architectures are needed. VR architectures in advanced electronic packaging architectures may include fully integrated voltage regulator (FIVR) solutions. In order to implement such power delivery architectures, capacitance is needed on the package substrate. The capacitance may be provided using discrete capacitors that are attached to the package substrate. In other instances, capacitor structures may be integrated into the manufacture of the package substrate. However, existing integrated capacitor architectures do not provide sufficient capacitance and/or the capacitors are not compatible with advanced glass core package substrates.

### BRIEF DESCRIPTION OF THE DRAWINGS

FIG. 1 is a cross-sectional illustration of a package substrate that includes an integrated capacitor structure, in accordance with an embodiment.

FIG. 2A is a perspective view illustration of the scaffolding for a capacitor structure with a plurality of pillars, in accordance with an embodiment.

FIG. 2B is a perspective view illustration of the scaffolding for a capacitor structure with a plurality of fins, in accordance with an embodiment.

FIG. 3A is a cross-sectional illustration of a capacitor structure over a pillar, in accordance with an embodiment.

FIG. 3B is a cross-sectional illustration of a capacitor structure with a multi-layer capacitor, in accordance with an embodiment.

FIG. 3C is a cross-sectional illustration of a capacitor structure with a scaffolding that includes non-planar sidewalls, in accordance with an embodiment.

FIGS. 4A-4I are cross-sectional illustrations depicting a process for forming a capacitor structure over a glass core, in accordance with an embodiment.

FIG. 5 is a cross-sectional illustration of a package substrate that includes an integrated capacitor structure with carbon nanotube pillars, in accordance with an embodiment.

FIGS. 6A-6F are cross-sectional illustration depicting a process for forming a capacitor structure with carbon nanotube pillars, in accordance with an embodiment.

FIG. 7 is a cross-sectional illustration of an electronic system with an integrated capacitor formed over a scaffold of pillars, in accordance with an embodiment.

FIG. 8 is a schematic of a computing device built in accordance with an embodiment.

### EMBODIMENTS OF THE PRESENT DISCLOSURE

Described herein is a glass substrate with super capacitors provided over the glass substrate, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, capacitive structures on the package substrate are necessary for advanced fully integrated voltage regulator (FIVR) architectures. Additionally, such capacitive structures need to be compatible with glass core solutions. Accordingly, embodiments disclosed herein include capacitive structures that are fabricated over a scaffolding of pillars or fins. In a first embodiment, the scaffolding is formed with a glass material (e.g., comprising silicon and oxygen). The scaffolding may have high aspect ratio pillars or fins. For example, height:width aspect ratios may be approximately 10:1 or greater. In some instances, the height of the pillars or fins may be approximately 200 nm or greater. Hundreds or thousands of pillars or fins may be fabricated in order to provide high capacitance values. In an embodiment, a capacitive structure is formed over the pillars or fins. The capacitive structure may include a first conductive layer, a dielectric layer, and a second conductive layer. The capacitive structure may have an upside down U-shaped cross-section since the capacitive structure is conformal to the scaffolding.

In another embodiment, the scaffolding may be part of the capacitive structure. For example, the scaffolding may comprise a conductive material that can be used as the first conductive layer. In such an embodiment, a dielectric layer and a second conductive layer may be conformally deposited over the scaffolding. The scaffolding may include any suitable conductive material. In a particular embodiment, the scaffolding comprises carbon nanotubes.

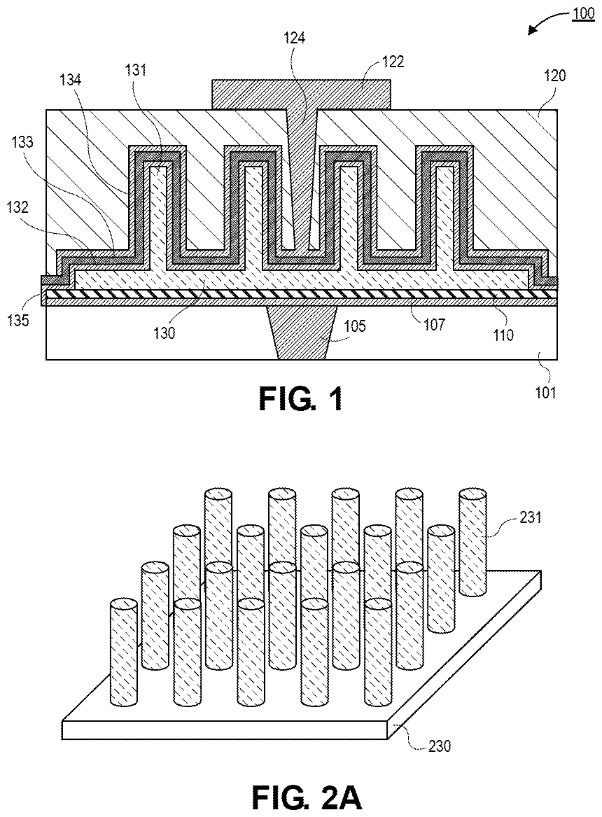

Referring now to FIG. 1, a cross-sectional illustration of a package substrate 100 is shown, in accordance with an embodiment. In an embodiment, the package substrate 100 comprises a core 101. The core 101 may be any suitable core material. For example, the core 101 may comprise a glass material in some embodiments. In an embodiment, a via 105 may pass through a thickness of the core 101. In the illustrated embodiment, the via 105 has a trapezoidal shape. In other embodiments, the via 105 may have an hourglass shaped cross-section.

In an embodiment, a conductive trace 107 may be provided over the core 101. The trace 107 may be electrically coupled to the via 105. A barrier layer 110 may be provided over a top surface of the trace 107. The barrier layer 110 may comprise any suitable material. For example, the barrier layer 110 may comprise silicon and nitrogen (e.g., silicon nitride). The barrier layer 110 provides a diffusion barrier that prevents the scaffolding (e.g., base 130 and pillars 131) from diffusing into the trace 107 and the via 105 during manufacture of the capacitor structure, as will be described in greater detail below.

In an embodiment, the capacitor structure may be fabricated over the scaffolding. For example, the scaffolding may include a base 130 and a plurality of pillars 131. The base 130 and the pillars 131 may comprise any suitable material. For example, the scaffolding may include silicon and oxygen (e.g., silicon oxide). The scaffolding may be formed with the deposition and patterning of a silicon layer, and the silicon layer may be oxidized to form the silicon oxide. A more detailed description of the process for forming the scaffolding is described in greater detail below.

In an embodiment, the pillars 131 may be high aspect ratio pillars 131. For example, a height:width ratio of the pillars 131 may be approximately 10:1 or greater, or approximately 25:1 or greater. In an embodiment, the pillars 131 may be formed to a height that is approximately 100 nm or greater, or approximately 200 nm or greater. As used herein, “approximately” may refer to a range of values that are within ten percent of the stated value. For example, approximately 100 nm may refer to a range between 90 nm and 110 nm.

In an embodiment, the capacitor structure may include a first conductive layer 132. The first conductive layer 132 may comprise any suitable conductive material, such as copper or the like. In an embodiment, the first conductive layer 132 may be electrically coupled to the trace 107 and the via 105. For example, a portion 135 of the first conductive layer 132 may wrap around an edge of the barrier layer 110. In other embodiments, a via through the barrier layer 110 may be provided to electrically couple the first conductive layer 132 to the trace 107.

In an embodiment, the capacitor structure may further include a dielectric layer 133. The dielectric layer 133 may be a high dielectric constant material. For example, the dielectric constant of dielectric layer 133 may be equal to or greater than the dielectric constant of a material comprising silicon and oxygen. In an embodiment, the dielectric layer 133 may be a thickness that is approximately 50 nm or less or approximately 20 nm or less.

In an embodiment, the capacitor structure may further include a second conductive layer 134. The second conductive layer 134 may be any suitable conductive material, such as copper or the like. In an embodiment, the second conductive layer 134 may be electrically coupled to a pad 122 formed over a buildup layer 120. The pad 122 may be electrically coupled to the second conductive layer 134 by a via 124 or the like.

In an embodiment, the capacitor structure may have an upside down U-shaped cross-section. That is, the capacitor structure may be formed along sidewalls of the pillars 131 and the top surfaces of the pillars 131. In some instances, the capacitor structure may be referred to as an inverted trench. The capacitor structure may have substantially vertical portions along sidewalls of the pillars 131, and substantially planar portions over the top surfaces of the pillars 131 and over the base 130.

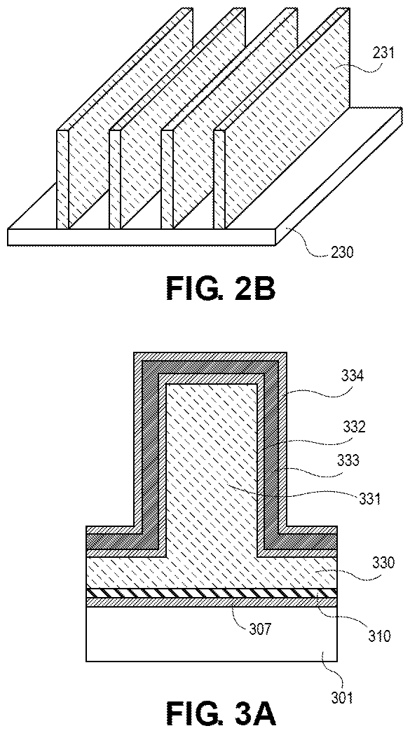

Referring now to FIG. 2A, a perspective view illustration of the scaffolding is shown, in accordance with an embodiment. As shown, the scaffolding may include a base 230. A plurality of pillars 231 may extend up from a surface of the base 230. In the illustrated embodiment, the pillars 231 have a cylindrical shape. Though it is to be appreciated that pillars 231 with any three-dimensional shape may be used (e.g., rectangular prism or the like). In an embodiment, the pillars 231 may have any suitable pitch. For example, the pillars 231 may be spaced at a pitch of approximately 100 nm or less in some embodiments. The pillars 231 may also have a high aspect ratio, such as 10:1 or greater or 25:1 or greater. In an embodiment, the scaffolding may comprise any suitable material. For example, the scaffolding may include a non-conductive material (e.g., a material comprising silicon and oxygen). In other embodiments, as will be described in greater detail below, the scaffolding may include a conductive material, such as carbon nanotubes.

Referring now to FIG. 2B, a cross-sectional illustration of scaffolding for a capacitor structure is shown, in accordance with an additional embodiment. As shown in FIG. 2B, the scaffolding may include a base 230 and a plurality of fins 231. In an embodiment, the fins may have a confined dimension (i.e., width) and an extended dimension (length). The length may be significantly longer than the width in order to form an extended structure. The height of the fins 231 may also be significantly larger than the width in order to provide high aspect ratio fins 231 (e.g., 10:1 or greater, or 25:1 or greater). In an embodiment, the fins 231 may be spaced at a pitch that is approximately 100 nm or less, or approximately 50 nm or less.

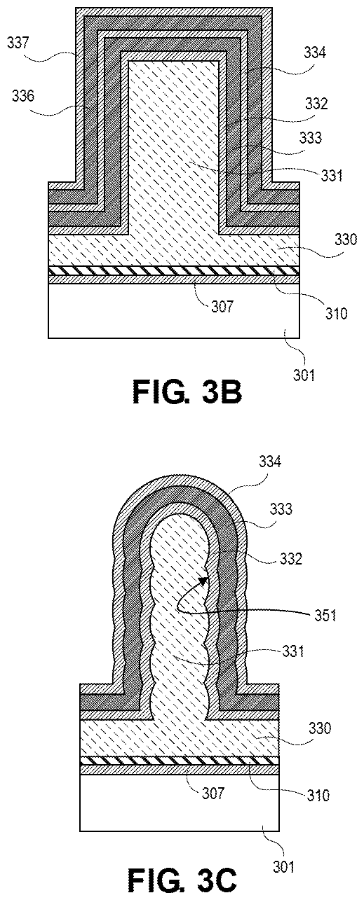

Referring now to FIG. 3A, a cross-sectional illustration of a portion of the capacitor structure is shown, in accordance with an embodiment. In the illustrated embodiment, a single pillar 331 is shown. However, it is to be appreciated that hundreds or thousands of pillars 331 may be used in the capacitor structure. In an embodiment, a core 301, such as a glass core is provided as an underlying substrate for the scaffolding. In an embodiment, a trace 307 is provided over the core 301. A barrier layer 310 may be provided over the trace 307.

In an embodiment, scaffolding is provided over the barrier layer 310. For example, the scaffolding may include a base 330 and a pillar 331. The scaffolding may be an electrically insulating material, such as a material comprising silicon and oxygen (e.g., silicon oxide). The pillar 331 may be a high aspect ratio pillar 331. For example, the pillar 331 may have an aspect ratio that is approximately 10:1 or greater, or approximately 25:1 or greater. In an embodiment, the pillar 331 may have sidewalls that are substantially vertical. That is, the sidewalls of the pillar 331 may be substantially orthogonal to a top surface of the core 301. Though, it is to be appreciated that the patterning process for the pillars 331 may result in pillars that have tapered sidewalls (e.g., with a width at the bottom of the pillar 331 greater than a width at the top of the pillar 331). The pillar 331 may also have a substantially planar top surface that is parallel to a top surface of the core 301. In other embodiments, the top surface of the pillar 331 may be rounded.

In an embodiment, the first conductive layer 332 may be directly in contact with the pillar 331. A dielectric layer 333 may be in direct contact with the first conductive layer 332, and a second conductive layer 334 may be in direct contact with the dielectric layer 333. In an embodiment, the capacitor structure is conformal to the pillar 331. That is, the capacitor structure may have an upside down U-shaped cross-section. For example, the opening of the U-shaped cross-section may face down towards the top surface of the core 301. The U-shaped cross-section may include substantially vertical portions over the sidewalls of the pillar 331, a horizontal portion along a top of the pillar 331, and horizontal portions along the base 330.

Referring now to FIG. 3B, a cross-sectional illustration of a capacitor structure over scaffolding is shown, in accordance with an additional embodiment. In an embodiment, the capacitor structure in FIG. 3B is substantially similar to the capacitor structure in FIG. 3A, with the addition of an additional capacitor layer. For example, a second dielectric layer 336 is provided over the second conductive layer 334. Additionally, a third conductive layer 337 is provided over the second dielectric layer 336. While a pair of two capacitors are shown in FIG. 3B, it is to be appreciated that any number of capacitor layers may be fabricated over the pillar 331 and the base 310. In an embodiment, the first capacitor (i.e., first conductive layer 332, dielectric layer 333, and second conductive layer 334) may be substantially similar to the second capacitor (i.e., second conductive layer 334, second dielectric layer 336, and third conductive layer 337). In other embodiments, the first capacitor may be different than the second capacitor.

Referring now to FIG. 3C, a cross-sectional illustration of a capacitor structure over scaffolding is shown, in accordance with yet another additional embodiment. In an embodiment, the capacitor structure in FIG. 3C is substantially similar to the capacitor structure in FIG. 3A with the exception of the sidewalls 351 of the pillar 331. Instead of being substantially vertical sidewalls, the sidewalls 351 may include a scalloped shape. The scalloped shape may be the result of the etching process used to fabricate the pillar 331. The degree of scalloping may be controlled by the process conditions of the etching process used to form the pillar 331. In an embodiment, the scalloping of sidewalls 351 may be substantially uniform. In other embodiments, the scalloping may be non-uniform. In an embodiment, a top surface of the pillar 331 may also be rounded. Since the capacitor structure is conformal to the pillar 331, the capacitor structure may also have a scalloped cross-section.

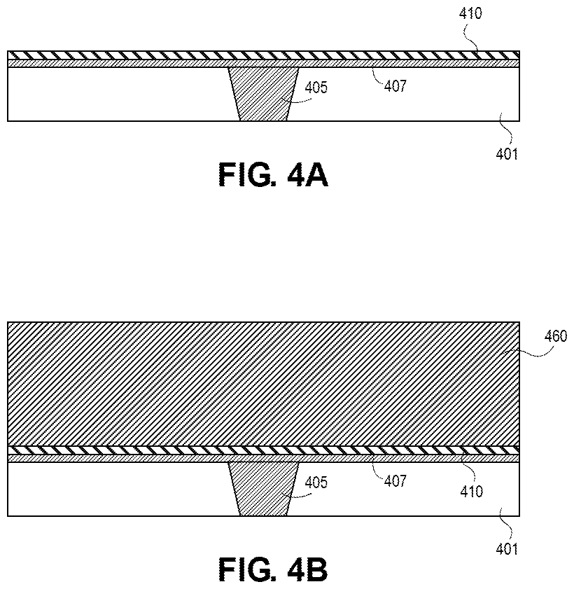

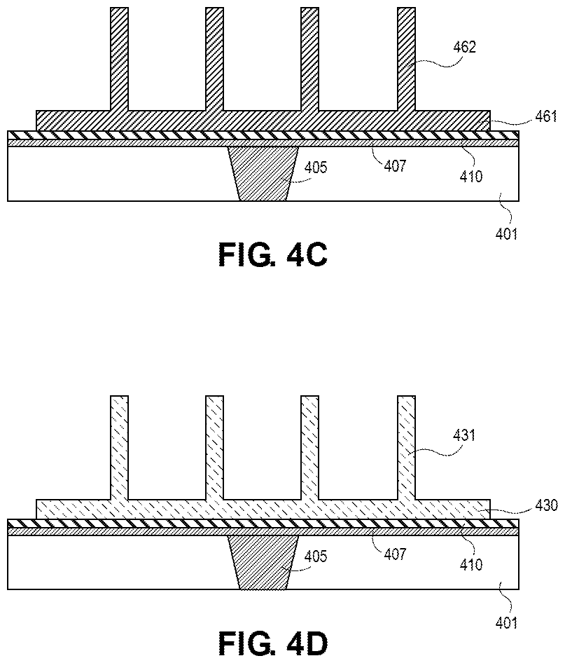

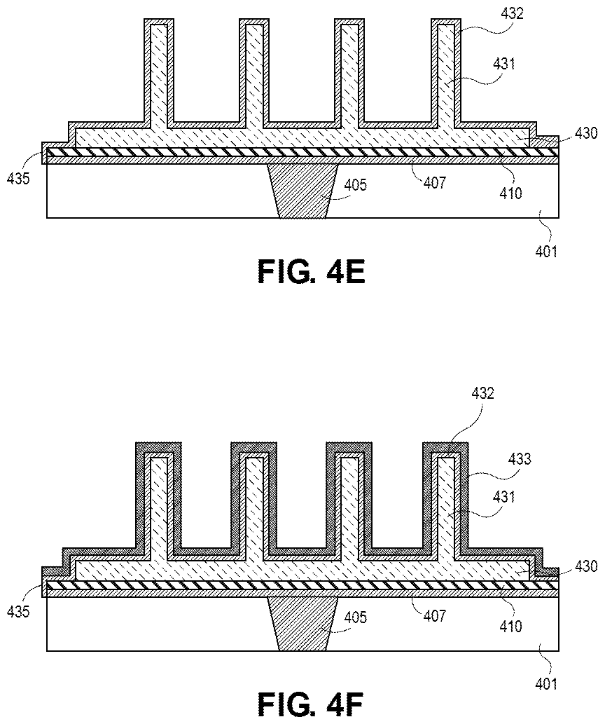

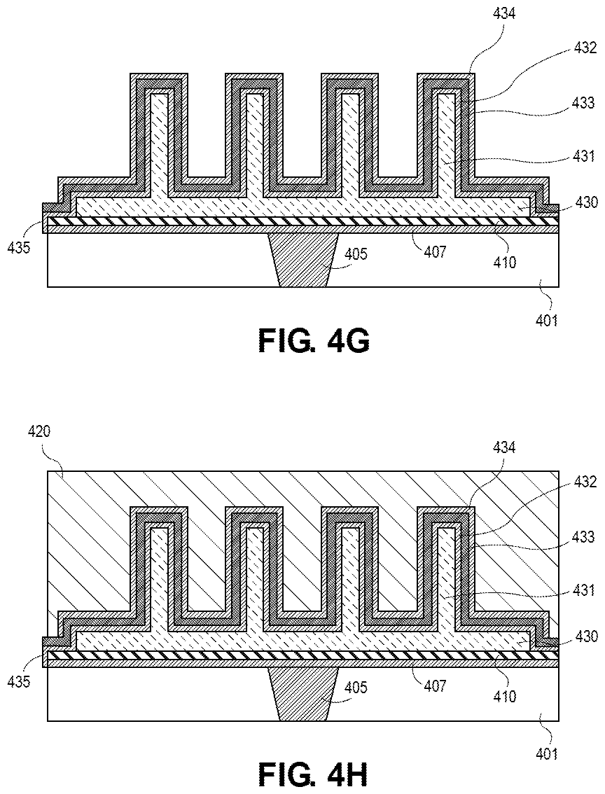

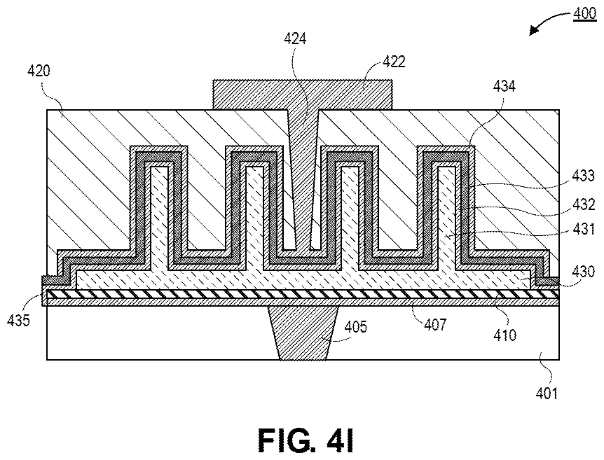

Referring now to FIGS. 4A-4I, a series of cross-sectional illustrations depicting a process for forming an integrated capacitor is shown, in accordance with an embodiment. In an embodiment, the integrated capacitor may be similar to the integrated capacitor shown in FIG. 1. However, it is to be appreciated that substantially similar processing operations may be used to form other capacitor structures described herein.

Referring now to FIG. 4A, a cross-sectional illustration of a core 401 is shown, in accordance with an embodiment. In an embodiment, the core 401 may comprise a glass material. In a particular embodiment, the core 401 may be a glass that is suitable for laser assisted patterning operations. For example, a via 405 may be formed through the core 401 by first exposing the core 401 to a laser that changes a microstructure or phase of the glass, etching the exposed region, and plating the via 405. In an embodiment, a trace 407 may also be formed above the via 405. The trace 407 may be electrically coupled to the via 405. The trace 407 and the via 405 may comprise any suitable conductive material, such as copper or the like. In an embodiment, a barrier layer 410 may be provided over the trace 407. The barrier layer 410 may comprise silicon and nitrogen (e.g., silicon nitride). Though, it is to be appreciated that other barrier layer materials may also be used in some embodiments.

Referring now to FIG. 4B, a cross-sectional illustration of the structure after a scaffolding layer 460 is deposited is shown, in accordance with an embodiment. In an embodiment, the scaffolding layer 460 may be a material that is compatible with high aspect ratio etching. In a particular embodiment, the scaffolding layer 460 may comprise silicon or any other semiconductor material. For example, the scaffolding layer 460 may comprise a polysilicon material. The scaffolding layer 460 may be deposited with any suitable deposition process, such as chemical vapor deposition (CVD) or the like. In an embodiment, the scaffolding layer 460 may have a height suitable for forming high aspect ratio pillars. In an embodiment, the scaffolding layer 460 may have a height of approximately 200 nm or greater, or approximately 500 nm or greater.

Referring now to FIG. 4C, a cross-sectional illustration of the structure after an etching process is shown, in accordance with an embodiment. In an embodiment, the etching process may result in the formation of high aspect ratio pillars 462 over a base 461. The high aspect ratio pillars 462 may be formed with any suitable anisotropic etching process. For example a deep ion etching process, a Bosch etching process, or the like may be used to form the pillars 462. While four pillars 462 are shown for simplicity, it is to be appreciated that hundreds or thousands of pillars 462 may be fabricated with the etching process. In an embodiment, the etching process may be stopped before etching entirely through the scaffolding layer 460 in order to provide a base 461. In an embodiment, the pillars 462 may have an aspect ratio of approximately 10:1 or greater, or approximately 25:1 or greater. The pillars 462 may have a height of approximately 200 nm or greater in some embodiments.

Referring now to FIG. 4D, a cross-sectional illustration of the structure after an oxidation process is shown, in accordance with an embodiment. The oxidation process may include a thermal oxidation process in an annealing chamber or the like. The oxidation process converts the silicon pillars 462 into insulating pillars 431 that may comprise silicon and oxygen (e.g., silicon oxide). Similarly, the base 461 may be converted into silicon oxide base 430. Since the annealing process is implemented at high temperatures that drive diffusion, the barrier layer 410 is provided. Accordingly, silicon from the base 430 and pillars 431 is prevented from diffusing into the trace 407 and the via 405.

Referring now to FIG. 4E, a cross-sectional illustration of the structure after a first conductive layer 432 is deposited is shown, in accordance with an embodiment. In an embodiment, the first conductive layer 432 may comprise copper or the like. The first conductive layer 432 may be deposited with a sputtering process or the like. As shown, the first conductive layer 432 is electrically coupled to the trace 407 by portion 435 that wraps around an edge of the barrier layer 410. In other embodiments, the portion 435 may be a via that passes through an opening in the barrier layer 410.

Referring now to FIG. 4F, a cross-sectional illustration of the structure after a dielectric layer 433 is provided over the first conductive layer 432 is shown, in accordance with an embodiment. In an embodiment, the dielectric layer 433 may be a high-k dielectric material. As used herein, a high-k dielectric material may refer to a material that has a dielectric constant that is equal to or greater than the dielectric constant of a material that comprises silicon and oxygen (e.g., silicon oxide). In an embodiment, a thickness of the dielectric layer 433 may be approximately 25 nm or less, or approximately 10 nm or less. The dielectric layer 433 may be deposited with a CVD or a plasma enhanced CVD (PECVD) process, or any other suitable deposition process.

Referring now to FIG. 4G, a cross-sectional illustration of the structure after a second conductive layer 434 is deposited over the dielectric layer 433 is shown, in accordance with an embodiment. In an embodiment, the second conductive layer 434 may comprise copper or the like. The second conductive layer 434 may be deposited with a sputtering process or the like.

Referring now to FIG. 4H, a cross-sectional illustration of the structure after a buildup layer 420 is deposited is shown, in accordance with an embodiment. The buildup layer 420 may be any suitable organic buildup film. In a particular embodiment, the buildup layer 420 is deposited over the capacitor structure with a lamination process or the like. The buildup layer 420 may embed the capacitor structure over the pillars 431.

Referring now to FIG. 4I, a cross-sectional illustration of the package substrate 400 after a via 424 and pad 422 are formed is shown, in accordance with an embodiment. In an embodiment, the via 424 passes through the buildup layer 420 in order to electrically couple the pad 422 to the second conductive layer 434. The via 424 may be formed with a laser drilling process, or any other via formation process.

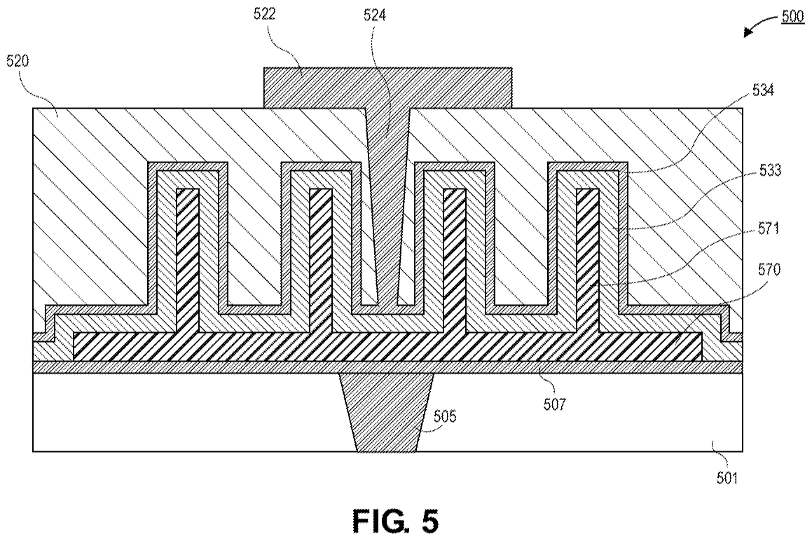

Referring now to FIG. 5, a cross-sectional illustration of a package substrate 500 is shown, in accordance with an additional embodiment. As shown, the package substrate 500 may comprise a core 501, such as a glass core. In an embodiment, a via 505 may pass through the core 501. A trace 507 may be provided over the core 501. In contrast to the embodiments described above, there may not be a barrier layer over the trace 507. This is because there is no high temperature annealing process needed in order to fabricate the package substrate 500 shown in FIG. 5. Instead, the base 570 and pillars 571 may be provided directly over the trace 507.

In an embodiment, the base 570 and the pillars 571 may comprise a conductive material. That is, instead of just being scaffolding, the base 570 and the pillars 571 may be functional parts of the capacitor structure. Primarily, the base 570 and the pillars 571 may be the first conductive layer of the capacitor structure. In an embodiment, the base 570 and the pillars 571 may comprise carbon. In a particular embodiment, the pillars 571 may comprise carbon nanotubes. The carbon nanotubes enable high aspect ratio pillars 571 that are conductive. The base 570 may be in direct contact with the trace 507. As such, the pillars 571 are electrically coupled to the trace 507 and the via 505.

In an embodiment, the capacitor structure may further comprise a dielectric layer 533 and a second conductive layer 534. The dielectric layer 533 may be a high-k dielectric material. In an embodiment, a thickness of dielectric layer 533 may be approximately 50 nm or less, or approximately 20 nm or less. In an embodiment, the dielectric layer 533 and the second conductive layer 534 are conformal to the pillars 571. In an embodiment, a via 524 electrically couples the second conductive layer 534 to a pad 522 over a buildup layer 520.

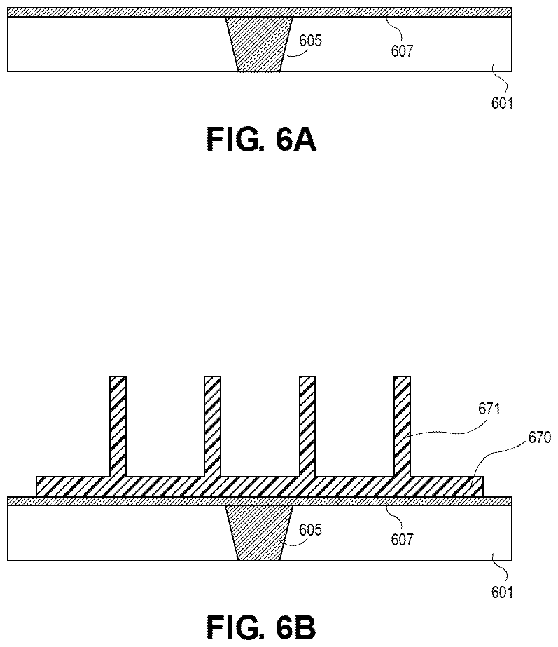

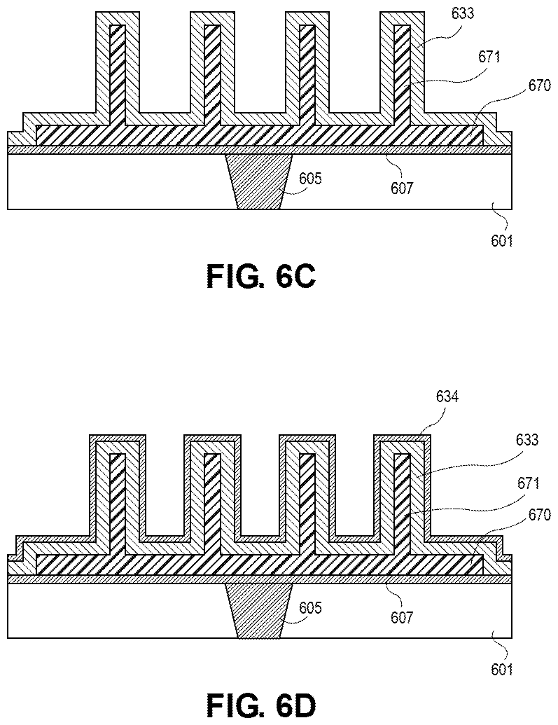

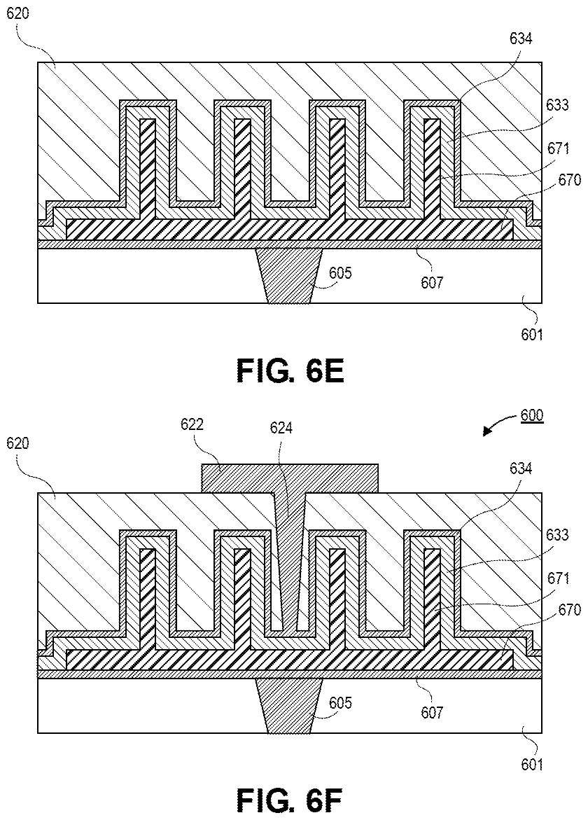

Referring now to FIGS. 6A-6F, a series of cross-sectional illustrations depicting a process for forming an integrated capacitor is shown, in accordance with an embodiment. In an embodiment, the integrated capacitor may be similar to the integrated capacitor shown in FIG. 5. However, it is to be appreciated that substantially similar processing operations may be used to form other capacitor structures described herein.

Referring now to FIG. 6A, a cross-sectional illustration of a core 601 is shown, in accordance with an embodiment. In an embodiment, the core 601 may comprise a glass material. In a particular embodiment, the core 601 may be a glass that is suitable for laser assisted patterning operations. For example, a via 605 may be formed through the core 601 by first exposing the core 401 to a laser that changes a microstructure or phase of the glass, etching the exposed region, and plating the via 605. In an embodiment, a trace 607 may also be formed above the via 605. The trace 607 may be electrically coupled to the via 605. The trace 607 and the via 605 may comprise any suitable conductive material, such as copper or the like.

Referring now to FIG. 6B, a cross-sectional illustration of the structure after a base 670 and pillars 671 are formed is shown, in accordance with an embodiment. In an embodiment, the base 670 and the pillars 671 may be conductive features. The base 670 and the pillars 671 may also comprise carbon. For example, the pillars 671 may comprise carbon nanotubes. In an embodiment, the base 670 and the pillars 671 may be formed with a CVD process or any other suitable process for forming carbon nanotube pillars 671. In an embodiment, the pillars 671 may be high aspect ratio pillars 671. For example, the pillars 671 may have an aspect ratio that is 10:1 or greater, or 25:1 or greater. The pillars 671 may have a height of 200 nm or greater, or of 500 nm or greater. In an embodiment, the base 670 is in direct contact with the trace 607. As such, the pillars 671 and the base 670 may be electrically coupled to the via 605.

Referring now to FIG. 6C, a cross-sectional illustration of the structure after a dielectric layer 633 is provided over the pillars 671 is shown, in accordance with an embodiment. In an embodiment, the dielectric layer 633 may be a high-k dielectric material. In an embodiment, a thickness of the dielectric layer 633 may be approximately 25 nm or less, or approximately 10 nm or less. The dielectric layer 633 may be deposited with a CVD or a PECVD process, or any other suitable deposition process.

Referring now to FIG. 6D, a cross-sectional illustration of the structure after a second conductive layer 634 is deposited over the dielectric layer 633 is shown, in accordance with an embodiment. In an embodiment, the second conductive layer 634 may comprise copper or the like. The second conductive layer 634 may be deposited with a sputtering process or the like.

Referring now to FIG. 6E, a cross-sectional illustration of the structure after a buildup layer 620 is deposited is shown, in accordance with an embodiment. The buildup layer 620 may be any suitable organic buildup film. In a particular embodiment, the buildup layer 620 is deposited over the capacitor structure with a lamination process or the like. The buildup layer 620 may embed the capacitor structure over the pillars 671.

Referring now to FIG. 6F, a cross-sectional illustration of the package substrate 600 after a via 624 and pad 622 are formed is shown, in accordance with an embodiment. In an embodiment, the via 624 passes through the buildup layer 620 in order to electrically couple the pad 622 to the second conductive layer 634. The via 624 may be formed with a laser drilling process, or any other via formation process.

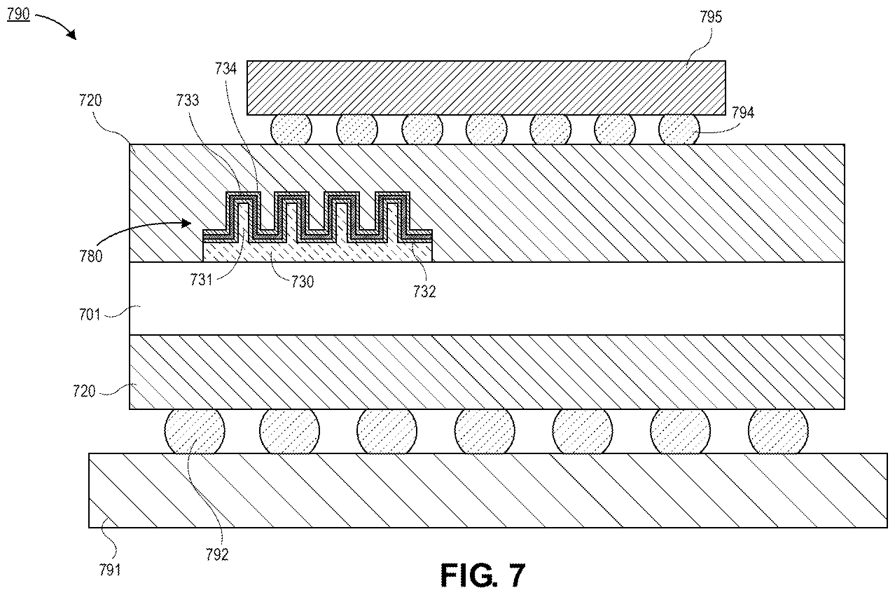

Referring now to FIG. 7, a cross-sectional illustration of an electronic system 790 is shown, in accordance with an embodiment. In an embodiment, the electronic system 790 may comprise a board 791. The board 791 may be coupled to a package substrate by interconnects 792, such as solder balls, sockets, or the like. In an embodiment, the package substrate may include a core 701 and buildup layers 720 above and below the core 701. In an embodiment, a capacitive structure 780 is provided over the core 701. The capacitive structure 780 may comprise scaffolding such as a base 730 and a plurality of pillars 731. In an embodiment, a first conductive layer 732 is over the pillars 731, a dielectric layer 733 is over the first conductive layer 732, and a second conductive layer 734 is over the dielectric layer 733. In other embodiments, the first conductive layer 732 may be omitted when the pillars 731 are a conductive material, such as a carbon nanotube material. In an embodiment, a die 795 is coupled to the package substrate through interconnects 794. The interconnects 794 may be any suitable first level interconnect (FLI) architecture.

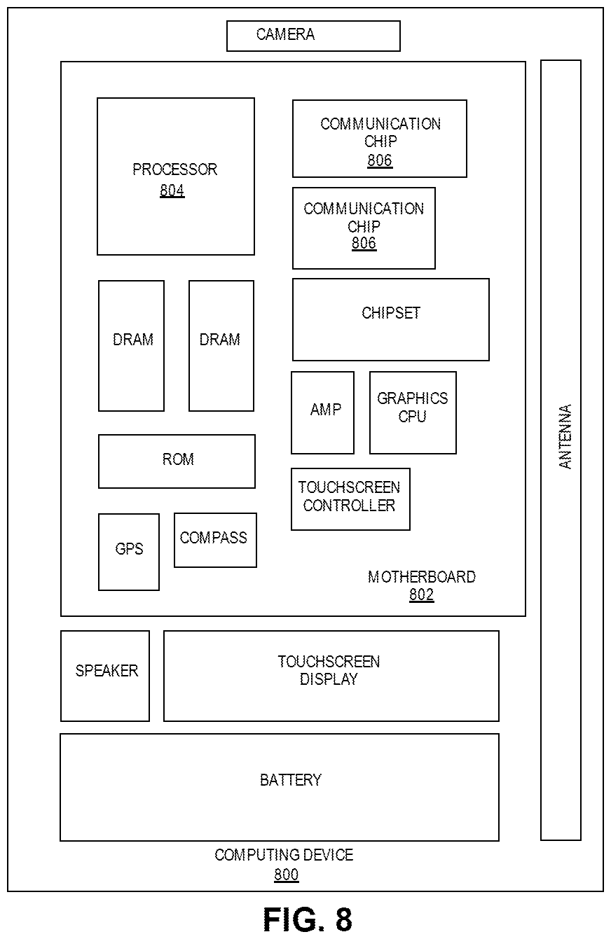

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic system that includes an integrated capacitor structure over pillar scaffolding, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic system that includes an integrated capacitor structure over pillar scaffolding, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a substrate, wherein the substrate comprises glass; a pillar over the substrate; a capacitor over the pillar, wherein the capacitor comprises: a first conductive layer on the pillar; a dielectric layer over the first conductive layer; and a second conductive layer over the dielectric layer.

Example 2: the electronic package of Example 1, wherein the pillar is separated from the substrate by at least a barrier layer.

Example 3: the electronic package of Example 2, wherein the barrier layer comprises silicon and nitrogen.

Example 4: the electronic package of Example 2 or Example 3, wherein a base is provided between the pillar and the barrier layer, wherein the base comprises the same material as the pillar.

Example 5: the electronic package of Examples 1-4, wherein the substrate comprises a via, and wherein a conductive trace is provided over the via.

Example 6: the electronic package of Example 5, wherein the first conductive layer is electrically coupled to the conductive trace.

Example 7: the electronic package of Examples 1-6, wherein the pillar is elongated to form a fin.

Example 8: the electronic package of Examples 1-7, wherein the dielectric layer has a dielectric constant that is equal to or higher than a dielectric constant of a material comprising silicon and oxygen.

Example 9: the electronic package of Examples 1-8, wherein the dielectric layer has a thickness of 50 nm or less.

Example 10: the electronic package of Examples 1-10, wherein a height of the pillar is approximately 200 nm or more.

Example 11: the electronic package of Example 10, wherein the pillar has an aspect ratio (height:width) of approximately 10:1 or greater.

Example 12: the electronic package of Examples 1-11, wherein the pillar comprises silicon and oxygen.

Example 13: an electronic package, comprising: a substrate, wherein the substrate comprises glass; a pillar over the substrate, wherein the pillar comprises carbon; a dielectric layer over the pillar; and a conductive layer over the dielectric layer.

Example 14: the electronic package of Example 13, wherein the pillar comprises a carbon nanotube.

Example 15: the electronic package of Example 13 or Example 14, further comprising: a via in the substrate; and a conductive trace over the via, wherein the conductive trace is between the pillar and the via.

Example 16: the electronic package of Example 15, further comprising: a base between the pillar and the conductive trace, wherein the base comprises carbon.

Example 17: the electronic package of Example 16, wherein the conductive trace directly contacts the base.

Example 18: the electronic package of Examples 13-17, wherein the pillar has an aspect ratio (height:width) that is approximately 10:1 or greater.

Example 19: the electronic package of Examples 13-18, wherein the dielectric layer comprises a dielectric constant that is equal to or higher than a dielectric constant of a material comprising silicon and oxygen.

Example 20: an electronic package, comprising: a substrate; a pillar over the substrate, where the pillar comprises sidewall surfaces and a top surface; a first conductive layer over the pillar, wherein the first conductive layer comprises an upside down U-shaped cross-section and is in direct contact with the sidewall surfaces and the top surface of the pillar; a dielectric layer over the first conductive layer, wherein the dielectric layer comprises an upside down U-shaped cross-section; and a second conductive layer over the dielectric layer, wherein the second conductive layer comprises an upside down U-shaped cross-section.

Example 21: the electronic package of Example 20, wherein the sidewall surfaces of the pillar are non-planar.

Example 22: the electronic package of Example 20 or Example 21, wherein the pillar comprises silicon and oxygen.

Example 23: an electronic system, comprising: a board; a package substrate coupled to the board, wherein the package substrate comprises: a core; and a capacitor over the core, wherein the capacitor comprises a plurality of pillars with a dielectric layer and a first conductive layer over the pillars; and a die coupled to the package substrate.

Example 24: the electronic system of Example 23, wherein the plurality of pillars comprise carbon nanotubes.

Example 25: the electronic system of Example 23, further comprising: a second conductive layer between the plurality of pillars and the dielectric layer, wherein the pillars are an electrically insulating material.

What is claimed is:

1. An electronic package, comprising:
a substrate, wherein the substrate comprises glass;
a pillar over the substrate;
a capacitor over the pillar, wherein the capacitor comprises:
a first conductive layer on the pillar;
a dielectric layer over the first conductive layer; and
a second conductive layer over the dielectric layer.

2. The electronic package of claim 1, wherein the pillar is separated from the substrate by at least a barrier layer.

3. The electronic package of claim 2, wherein the barrier layer comprises silicon and nitrogen.

4. The electronic package of claim 2, wherein a base is provided between the pillar and the barrier layer, wherein the base comprises the same material as the pillar.

5. The electronic package of claim 1, wherein the substrate comprises a via, and wherein a conductive trace is provided over the via.

6. The electronic package of claim 5, wherein the first conductive layer is electrically coupled to the conductive trace.

7. The electronic package of claim 1, wherein the pillar is elongated to form a fin.

8. The electronic package of claim 1, wherein the dielectric layer has a dielectric constant that is equal to or higher than a dielectric constant of a material comprising silicon and oxygen.

9. The electronic package of claim 1, wherein the dielectric layer has a thickness of 50 nm or less.

10. The electronic package of claim 1, wherein a height of the pillar is approximately 200 nm or more.

11. The electronic package of claim 10, wherein the pillar has an aspect ratio (height:width) of approximately 10:1 or greater.

12. The electronic package of claim 1, wherein the pillar comprises silicon and oxygen.

13. An electronic package, comprising:
a substrate, wherein the substrate comprises glass;
a pillar over the substrate, wherein the pillar comprises carbon;
a dielectric layer over the pillar; and
a conductive layer over the dielectric layer.

14. The electronic package of claim 13, wherein the pillar comprises a carbon nanotube.

15. The electronic package of claim 13, further comprising:
a via in the substrate; and
a conductive trace over the via, wherein the conductive trace is between the pillar and the via.

16. The electronic package of claim 15, further comprising:
a base between the pillar and the conductive trace, wherein the base comprises carbon.

17. The electronic package of claim 16, wherein the conductive trace directly contacts the base.

18. The electronic package of claim 13, wherein the pillar has an aspect ratio (height:width) that is approximately 10:1 or greater.

19. The electronic package of claim 13, wherein the dielectric layer comprises a dielectric constant that is equal to or higher than a dielectric constant of a material comprising silicon and oxygen.

20. An electronic package, comprising:
a substrate;
a pillar over the substrate, where the pillar comprises sidewall surfaces and a top surface;
a first conductive layer over the pillar, wherein the first conductive layer comprises an upside down U-shaped cross-section and is in direct contact with the sidewall surfaces and the top surface of the pillar;
a dielectric layer over the first conductive layer, wherein the dielectric layer comprises an upside down U-shaped cross-section; and
a second conductive layer over the dielectric layer, wherein the second conductive layer comprises an upside down U-shaped cross-section.

21. The electronic package of claim 20, wherein the sidewall surfaces of the pillar are non-planar.

22. The electronic package of claim 20, wherein the pillar comprises silicon and oxygen.

23. An electronic system, comprising:
a board;
a package substrate coupled to the board, wherein the package substrate comprises:
a core; and
a capacitor over the core, wherein the capacitor comprises a plurality of pillars with a dielectric layer and a first conductive layer over the pillars; and
a die coupled to the package substrate.

24. The electronic system of claim 23, wherein the plurality of pillars comprise carbon nanotubes.

25. The electronic system of claim 23, further comprising: a second conductive layer between the plurality of pillars and the dielectric layer, wherein the pillars are an electrically insulating material.
